(19) United States
(12) Patent Application Publication
(10) Pub. No.: US 2025/0203773 A1
(43) Pub. Date: Jun. 19, 2025

(54) SEMICONDUCTOR PACKAGE AND METHODS OF FORMATION

(71) Applicant: Micron Technology, Inc., Boise, ID (US)

(72) Inventors: Kelvin Aik Boo TAN, Singapore (SG); Seng Kim YE, Singapore (SG); Chin Hui CHONG, Singapore (SG); Hong Wan NG, Singapore (SG); Ling PAN, Singapore (SG); See Hiong LEOW, Singapore (SG)

(21) Appl. No.: 18/960,992

(22) Filed: Nov. 26, 2024

Related U.S. Application Data
(60) Provisional application No. 63/611,488, filed on Dec. 18, 2023.

(51) Int. Cl. H05K 1/11; H01L 21/48; H01L 23/00; H01L 23/498; H01L 25/065; H01L 25/18; H05K 1/02; H05K 1/03; H05K 1/18; H05K 3/18; H05K 3/30; H05K 3/34

(52) U.S. Cl. CPC H05K 1/111; H01L 21/4853; H01L 23/49838; H01L 24/13; H01L 24/14; H01L 24/16; H01L 24/66; H01L 24/67; H01L 24/69; H01L 24/81; H01L 25/0655; H01L 25/0657; H01L 25/18; H05K 1/0271; H05K 1/0306; H05K 1/181; H05K 3/188; H05K 3/303; H05K 3/3436; H01L 24/73; H01L 2224/16227; H01L 2224/66; H01L 2224/67; H01L 2224/69; H01L 2224/81815; H01L 2924/351; H05K 2201/09227; H05K 2201/0939; H05K 2201/09409; H05K 2201/10159; H05K 2201/10522; H05K 2201/10734; H05K 2203/043; H05K 2203/0723

(57) ABSTRACT

Some implementations herein provide a semiconductor package and methods of formation. The semiconductor package includes a semiconductor die having a first set of conductive structures connected with a substrate having a second set of conductive structures, where a profile of heights of the second set of conductive structures includes a curvature relative to a surface of the substrate. The curvature is configured to compensate for warpage (e.g., offset warpage) that may be induced to the semiconductor die and/or the substrate during a reflow process that joins the semiconductor die and the substrate. By compensating for the warpage, a planarity of an interface region including solder joints between the first and second sets of conductive structures is increased. Increasing the planarity may reduce solder joint defects in the semiconductor package relative to another semiconductor package including another substrate having conductive structures without the profile having the curvature.

### CROSS-REFERENCE TO RELATED APPLICATION

This Patent application claims priority to U.S. Provisional Patent Application No. 63/611,488, filed on Dec. 18, 2023, entitled “SEMICONDUCTOR PACKAGE AND METHODS OF FORMATION,” which is hereby expressly incorporated by reference herein.

### TECHNICAL FIELD

The present disclosure generally relates to semiconductor devices and methods of forming semiconductor devices. For example, the present disclosure relates to a semiconductor package and methods of formation.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pad structures, or other electrical a set of conductive structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIGS. 3A and 3B are diagrams of an example implementation described herein.

FIGS. 4A and 4B are diagrams of an example implementation described herein.

FIG. 5 is a flowchart of an example method associated with forming a substrate described herein.

FIG. 6 is a flowchart of an example method associated with forming a semiconductor package described herein.

FIGS. 7A-7D are an example series of manufacturing operations that may be performed to form a substrate having a set of conductive structures described herein.

FIG. 8 is a diagram of an example implementation described herein.

FIG. 9 is a diagram of an example implementation described herein.

### DETAILED DESCRIPTION

A semiconductor package (e.g., a semiconductor device assembly) may include a substrate (e.g., and interposer) and one or more semiconductor components stacked on and/or over the substrate. For example, the semiconductor package may correspond to a flip chip type of semiconductor package, where a semiconductor die is connected to the substrate using a combination of conductive structures between the semiconductor die and the substrate. The combination of conductive structures may include a first set of conductive structures (e.g., an array of pillar and/or bump structures) on the semiconductor die that are joined with a second set of conductive structures (e.g., an array of pad structures or electrical traces) on the substrate. The first set of conductive structures and the second set of conductive structures may be joined using a reflow process that creates solder joints between the first and second sets of conductive structures.

In some cases, a thickness of the semiconductor die may be such that thermal stresses and/or strains during the reflow process cause the semiconductor die to warp. Additionally, or alternatively and during the reflow process, the substrate may warp. The warpage of the semiconductor die and/or the substrate may cause a profile of the first set of conductive structures and/or the second set of conductive structures to have a curvature that inhibits formation of reliable solder joints between the first and second sets of conductive structures. Examples of solder joint defects that may be induced by the curvature include non-wetting open solder joint defects and head-in-pillow solder joint defects.

Some implementations herein provide a semiconductor package and methods of formation. The semiconductor package includes a semiconductor die having a first set of conductive structures connected with a substrate having a second set of conductive structures, where a profile of heights of the second set of conductive structures includes a curvature relative to a surface of the substrate. The curvature is configured to compensate for warpage (e.g., offset warpage) that may be induced to the semiconductor die and/or the substrate during a reflow process that joins the semiconductor die and the substrate. By compensating for the warpage, a planarity of an interface region including solder joints between the first and second sets of conductive structures is increased. Increasing the planarity may reduce solder joint defects in the semiconductor package relative to another semiconductor package including another substrate having conductive structures without the profile having the curvature.

In this way, a quality and reliability of the semiconductor package is improved. By improving the quality and the reliability of the semiconductor package, an amount of resources used to support a market consuming the semiconductor package (e.g., labor, semiconductor manufacturing tools, raw materials, and/or computing resources) is reduced.

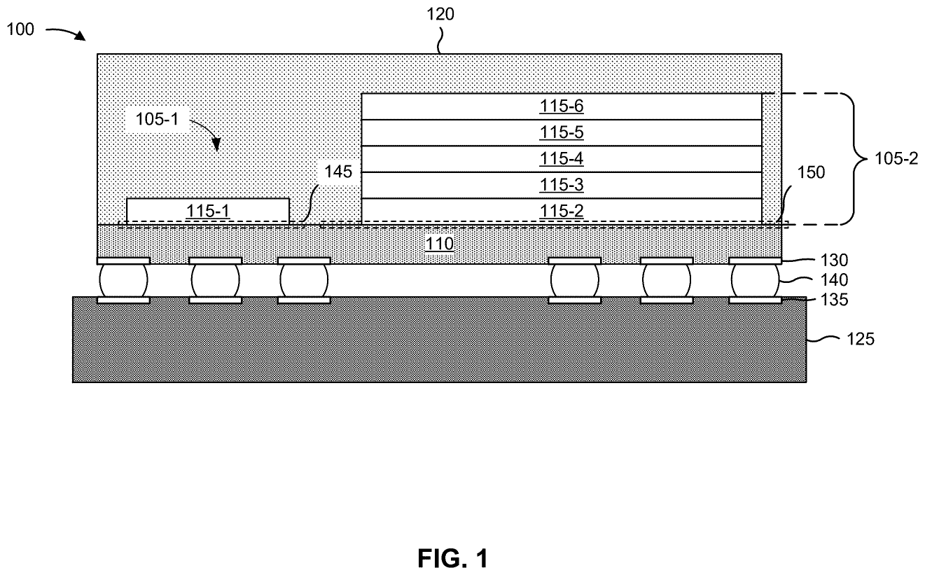

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a logic integrated circuit, a field-programmable gate array (FPGA), and/or a memory integrated circuit (e.g., a NAND memory device, a NOR memory device, a RAM device, or a ROM device), among other examples. The substrate 110 may include a multi-layer printed circuit board substrate (PCB), a ceramic substrate, or a silicon substrate with one or more conductive redistribution layers (RDL), among other examples.

An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die (sometimes called a die), as shown by the die 115-1. In some implementations, an integrated circuit 105 may include multiple semiconductor dies 115 (sometimes called dies), as shown by the second integrated circuit 105-2, which is shown as including five semiconductor dies 115-2 through 115-6.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-2 (sometimes called a bottom die or a base die) may be disposed on the substrate 110, a second die 115-3 may be disposed on the first die 115-2, and so on. Although FIG. 1 shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pad structures) of the substrate 110 are electrically connected to electrical contacts 135 (e.g., bond pad structures) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pad structures (e.g., bond pad structures) that are electrically connected to corresponding electrical pad structures (e.g., bond pad structures) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

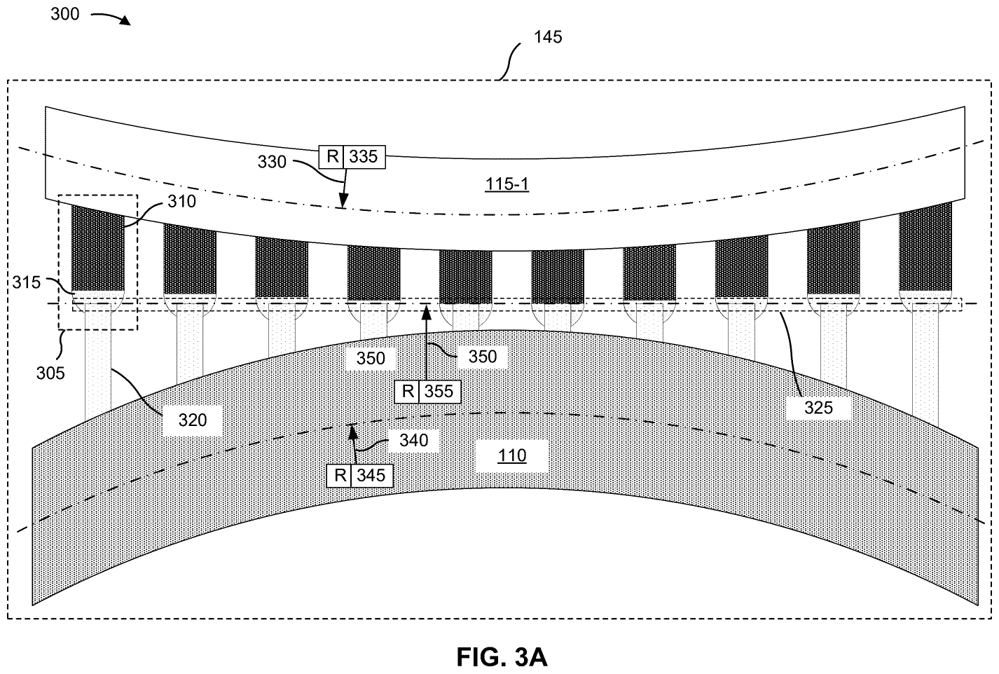

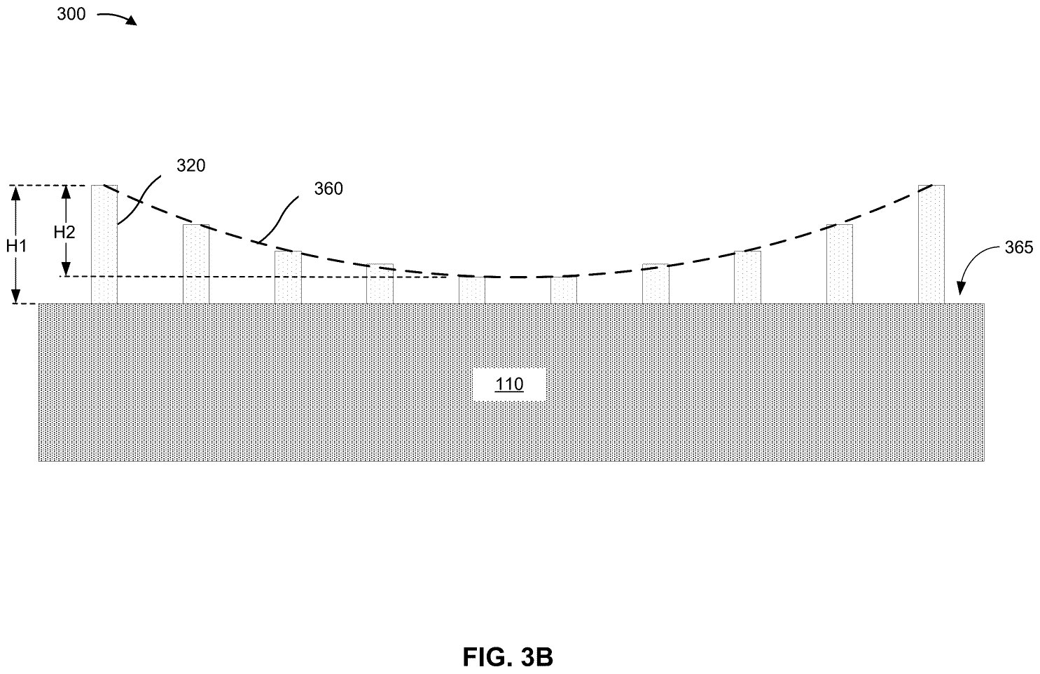

In some implementations, one or more of the dies is a flip chip die, where the flip chip die includes an array of a set of conductive structures (e.g., pillars or bumps) that face the substrate 110 and connect with pad structures and/or electrical traces on the substrate 110. For example, and as described in greater detail in connection with FIGS. 3A, 3B, 4A, 4B, 9, and elsewhere herein, the dies 115-1 and/or 115-2 may use an array of pillars, solder balls, and or bumps to connect to pad structures or electrical traces included in regions 145 and/or 150 of the substrate 110. Furthermore, and in some implementations, thicknesses of pad structures and/or electrical traces within the regions 145 and/or 150 are varied to create a profile of the pad structures and/or electrical traces that compensates for warpage of the die 115-1 and/or the substrate within the region 145 and/or the region 150. By compensating for the warpage, defects such as non-wetting open failures and/or head-in pillow failures may be reduced, to improve a quality and/or a reliability of the apparatus 100.

As indicated above, FIG. 1 is provided as an example. Other examples may differ from what is described with regard to FIG. 1.

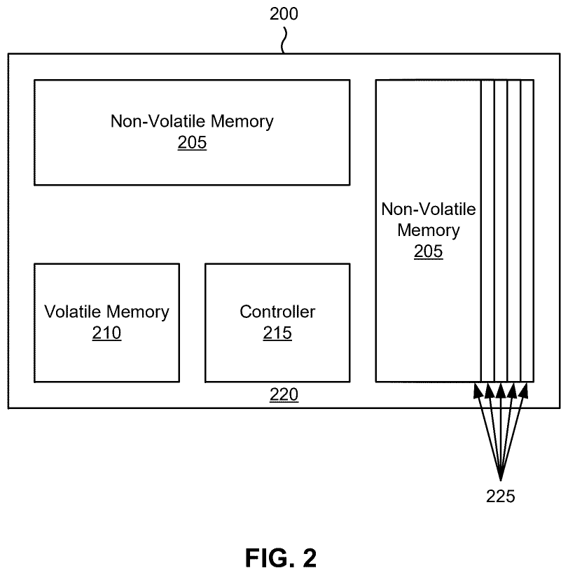

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

FIGS. 3A and 3B are diagrams of an example implementation 300 described herein. The implementation 300 may correspond to the region 145 of the apparatus 100 of FIG. 1. Alternatively, the implementation 300 may correspond to a semiconductor package including a single die (e.g., the die 115-1). In implementation 300, a reflow process that joins the substrate 110 and the die 115-1 induces a first warpage to the substrate 110 and a second warpage to the die 115-1. In implementation 300, the first warpage extends toward the die 115-1, and the second warpage extends toward the substrate 110. In other words, the warpages of the substrate 110 and the die 115-1 have opposite curvatures (e.g., curvatures with opposite orientations) that extend toward one another.

As shown in FIG. 3A, a set of conductive structures 305 is on the die 115-1. The set of conductive structures 305 may include pillar structures 310 and solder balls 315 that are on (e.g., connected with) the pillar structures 310. The pillar structures 310 may include a conductive material such as a copper material (Cu), a gold material (Au), a silver material (Ag), or another suitable conductive material. The solder balls 315 may include a solderable alloy such as a tin-lead (Sn—Pb) alloy, a tin-silver-copper (Sn—Ag—Cu) alloy, a tin-copper (Sn—Cu) alloy, or another suitable solderable alloy.

As further shown in FIG. 3A, a set of conductive structures 320 is on the substrate 110. The set of conductive structures 320 may correspond to pad structures, electrical traces, and/or bumps that are on the substrate 110, among other examples. The set of conductive structures 320 may include a combination of one or more conductive materials such as a copper material (Cu), an aluminum material (Al), a tin material (Sn), a nickel material (Ni), a silver material (Ag), a gold material (Au), or another suitable conductive material.

The sets of conductive structures 305 and 320 join within an interface region 325. The interface region 325 includes solder joints between the solder balls 315 and the set of conductive structures 320, where the solder joints are formed by a surface mount (SMT) and reflow process that temporarily elevates a temperature of the solder balls 315 to a liquid or semi-liquid phase, joins the solder balls 315 with conductive structures 320, and cools the temperature of the solder balls 315 to a solid phase that forms the solder joints.

As shown in FIG. 3A, the die 115-1 includes a curvature 330 having a radius of curvature 335 and the substrate 110 includes a curvature 340 having a radius of curvature 345. Further, and as shown in FIG. 3A, the interface region 325 includes a curvature 350 having a radius of curvature 355, where the radius of curvature 355 is greater than the radius of curvature 335 and/or the radius of curvature 345. In other words, the interface region 325 is “flatter” than the substrate 110 and/or the die 115-1.

As described in greater detail in connection with FIG. 3B, a profile of heights of the set of conductive structures 320 relative to the substrate 110 may compensate for the curvature 330 and/or the curvature 340 to improve a coplanarity of solder joints within the interface region 325. As an example, implementing such a profile may cause the coplanarity of the solder joints within the interface region 325 to be less than approximately 10 microns (μm). Additionally, or alternatively and in other words, implementing such a profile may cause the coplanarity of the solder joints to be included in a range of approximately −5 μm to approximately +5 μm. However, other values and ranges for the coplanarity are within the scope of the present disclosure.

FIG. 3B shows details related to the set of conductive structures 320 on the substrate 110. As shown in FIG. 3B, the set of conductive structures 320 includes a distribution of heights (e.g., heights H) that forms a curved profile 360 (e.g., a profile based on variations in the heights H) relative to a surface 365 of the substrate 110. In some implementations, a difference in the heights H across the curved profile 360 (e.g., a difference between H1 and H2) may be up to approximately 50 μm. However, other differences in the heights H are within the scope of the present disclosure.

The curved profile 360 may be determined using one or more modeling techniques that quantify an expected warpage of the substrate 110 and/or the die 115-1, such as a finite element analysis (FEA) modeling technique. Additionally, or alternatively, the curved profile 360 may be empirically determined using an interferometry measurement technique or a laser measurement technique that measures a warpage of the substrate 110 and/or the die 115-1 after the SMT and reflow process that joins the substrate 110 and the die 115-1.

As shown in FIG. 3B, the curved profile 360 is a concave profile, where a curvature of the curved profile 360 curves toward the surface 365. In some implementations, the curved profile 360 is a two-dimensional profile. In some implementations, the curved profile 360 is a three-dimensional profile (e.g., a “bowl-shaped” profile). Further, and in some implementations, the curved profile 360 is a symmetric profile (e.g., includes a symmetric curvature).

As indicated above, FIGS. 3A and 3B are provided as an example. Other examples may differ from what is described with respect to FIGS. 3A and 3B.

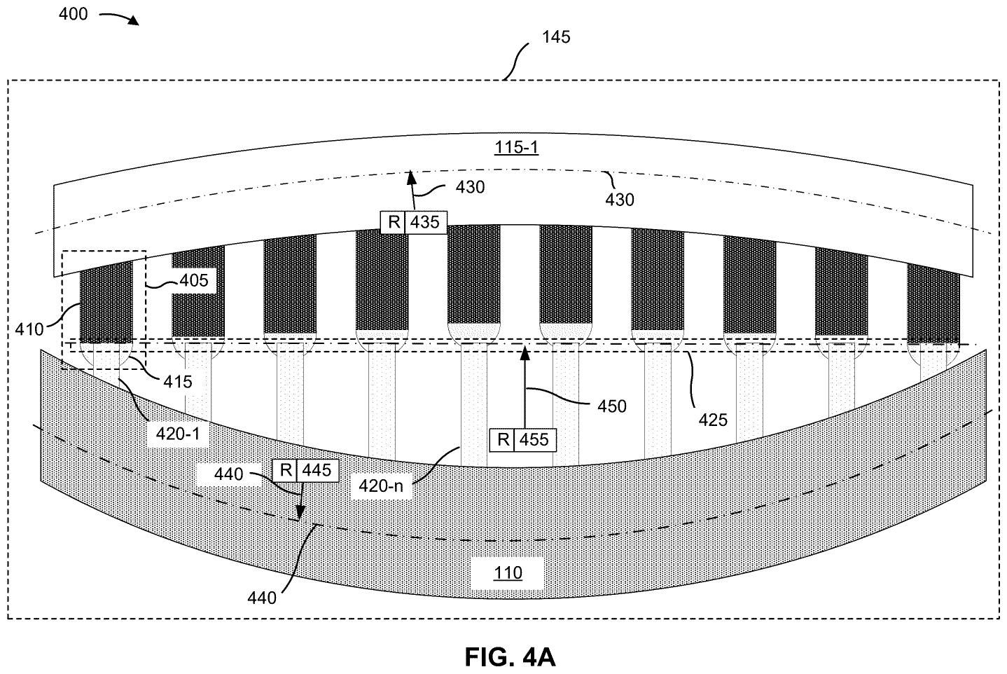

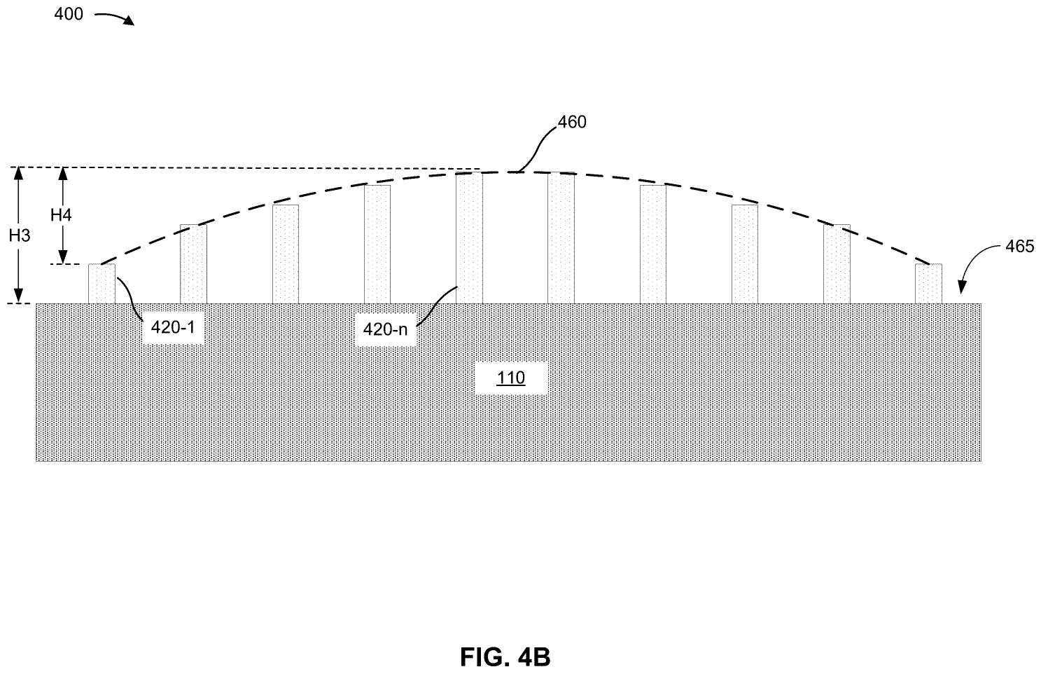

FIGS. 4A and 4B are diagrams of an example implementation 400 described herein. FIGS. 4A and 4B show a detailed view of the region 145 of FIG. 1. In implementation 400, a reflow process that joins the substrate 110 and the die 115-1 induces a first warpage to the substrate 110 and a second warpage to the die 115-1. In implementation 300, the first warpage extends way from the die 115-1, and the second warpage extends away from substrate 110. In other words, the warpages of the substrate 110 and the die 115-1 have opposite curvatures that extend toward one another.

As shown in FIG. 4A, a set of conductive structures 405 is on the die 115-1. The set of conductive structures 405 may include pillar structures 410 and solder balls 415 that are on (e.g., connected with) the pillar structures 410. The pillar structures 410 may include a conductive material such as a copper material (Cu), a gold material (Au), a silver material (Ag), or another suitable conductive material. The solder balls 415 may include a solderable alloy such as a tin-lead (Sn—Pb) alloy, a tin-silver-copper (Sn—Ag—Cu) alloy, a tin-copper (Sn—Cu) alloy, or another suitable solderable alloy.

As further shown in FIG. 4A, a set of conductive structures 420 are on the substrate 110. The set of conductive structures 420 may correspond to pad structures, electrical traces, and/or bumps that are on the substrate 110, among other examples. The set of conductive structures 420 may include a combination of one or more conductive materials such as a copper material (Cu), an aluminum material (Al), a tin material (Sn), a nickel material (Ni), a silver material (Ag), a gold material (Au), or another suitable conductive material.

The sets of conductive structures 405 and 420 join within an interface region 425. The interface region 425 includes solder joints between the solder balls 415 and the set of conductive structures 420, where the solder joints are formed by a surface mount (SMT) and reflow process that temporarily elevates a temperature of the solder balls 415 to a liquid or semi-liquid phase, joins the solder balls 415 with conductive structures 420, and cools the temperature of the solder balls 415 to a solid phase that forms the solder joints.

As shown in FIG. 4A, the die 115-1 includes a curvature 430 having a radius of curvature 435 and the substrate 110 includes a curvature 440 having a radius of curvature 445. Further, and as shown in FIG. 4A, the interface region 425 includes a curvature 450 having a radius of curvature 455, where the radius of curvature 455 is greater than the radius of curvature 435 and/or the radius of curvature 445. In other words, the interface region 425 is “flatter” than the substrate 110 and/or the die 115-1.

As described in greater detail in connection with FIG. 4B, a profile of heights of the set of conductive structures 420 relative to the substrate 110 may compensate for the curvature 430 and/or the curvature 440 to improve a coplanarity of solder joints within the interface region 425. As an example, implementing such a profile may cause the coplanarity of the solder joints within the interface region 425 to less than 10 microns (μm). Additionally, or alternatively and in other words, implementing such a profile may cause the coplanarity of the solder joints to be included in a range of approximately −5 μm to approximately +5 μm. However, other values and ranges for the coplanarity are within the scope of the present disclosure.

FIG. 4B shows details related to the set of conductive structures 420 on the substrate 110. As shown in FIG. 4B, the set of conductive structures 420 includes a distribution of heights (e.g., heights H) that forms a curved profile 460 (e.g., a profile of the heights H) relative to a surface 465 of the substrate 110. In some implementations, a difference in the heights H across the curved profile 460 (e.g., a difference between H3 and H4) may be up to approximately 50 μm. However, other differences in the heights H are within the scope of the present disclosure.

The curved profile 460 may be determined using one or more modeling techniques that quantify an expected warpage of the substrate 110 and/or the die 115-1, such as an FEA modeling technique. Additionally, or alternatively, the curved profile 460 may be empirically determined using an interferometry measurement technique or a laser measurement technique that measures a warpage of the substrate 110 and/or the die 115-1 after the SMT and reflow process that joins the substrate 110 and the die 115-1.

As shown in FIG. 4B, the curved profile 460 is a convex profile, where a curvature of the curved profile 460 curves away from the surface 465. In some implementations, the curved profile 460 is a two-dimensional profile. In some implementations, the curved profile 460 is a three-dimensional profile (e.g., a “dome-shaped”profile). Further, and in some implementations, the curved profile 460 is a symmetric profile (e.g., includes an asymmetric curvature).

As indicated above, FIGS. 4A and 4B are provided as an example. Other examples may differ from what is described with respect to FIGS. 4A and 4B.

As described in connection with FIGS. 3A, 3B, 4A, and 4B, a set of conductive structures (e.g., the set of conductive structures 320 and/or 420) formed on a substrate of a semiconductor package (e.g., the substrate 110 of the apparatus 100) may include a curved profile (e.g., the curved profile 360 and/or 460). The curved profile may compensate for a warpage of the substate and/or a die (e.g., the die 115-1) to improve a coplanarity of solder joints connecting the substrate and the die. In this way, a quality and reliability of the semiconductor package is improved. By improving the quality and the reliability of the semiconductor package, an amount of resources used to support a market consuming the semiconductor package (e.g., labor, semiconductor manufacturing tools, raw materials, and/or computing resources) is reduced.

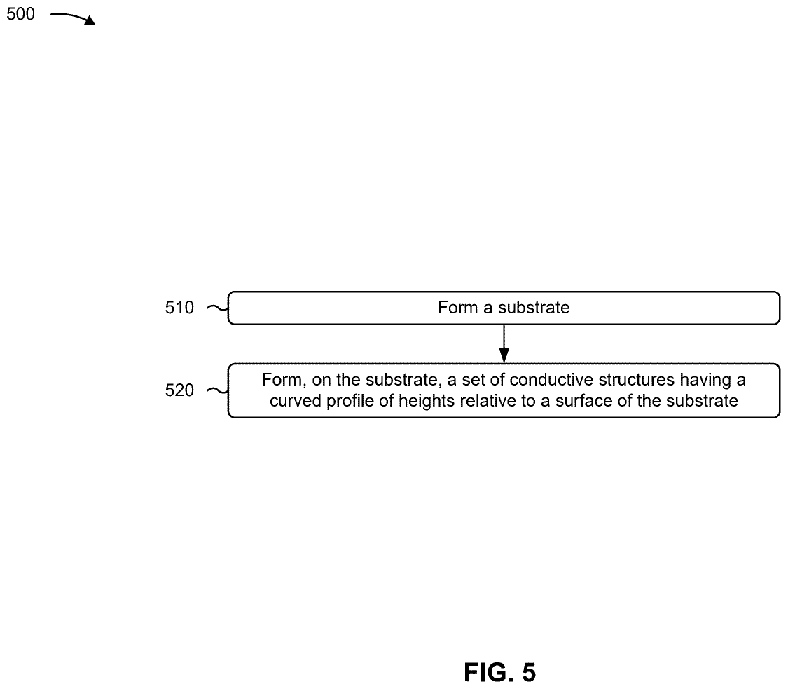

FIG. 5 is a flowchart of an example method 500 associated with forming a substrate described herein. In some implementations, one or more semiconductor processing tools of a substrate manufacturing facility (e.g., a laminating tool, a lithography tool, a dispense tool, an electroplating tool, a screen-printing tool, a reflow tool, an etch tool, and/or a substrate transport tool) may perform or may be configured to perform the method 500. Thus, means for performing the method 500 may include the one or more semiconductor processing tools and/or one or more components of the one or more semiconductor processing tools. Additionally, or alternatively, a non-transitory computer-readable medium may store one or more instructions that, when executed by the one or more semiconductor processing tools, cause the one or more semiconductor processing tools to perform the method 500.

As shown in FIG. 5, the method 500 may include forming a substrate (block 510). As further shown in FIG. 5, the method 500 may include forming, on the substrate (e.g., the substrate 110), a set of conductive structures (e.g., the set of conductive structures 320 or 420) having a curved profile of heights (e.g., the curved profile 360 or 460) relative to a surface (e.g., the surface 365 or 465) of the substrate (block 520).

The method 500 may include additional aspects, such as any single aspect or any combination of aspects described below and/or described in connection with one or more other methods or operations described elsewhere herein.

In a first aspect, forming the set of conductive structures having the curved profile of heights relative to the surface of the substrate includes forming at least a portion of the set of conductive structures to include a convex profile of heights that faces away from the surface of the substrate.

In a second aspect, alone or in combination with the first aspect, forming the set of conductive structures having the curved profile of heights relative to the surface of the substrate includes forming at least a portion of the set of conductive structures to include a concave profile of heights that faces toward the surface of the substrate.

In a third aspect, alone or in combination with one or more of the first and second aspects, forming the set of conductive structures includes forming the set of conductive structures from one or more of a copper material, an aluminum material, a tin material, a nickel material, a silver material, or a gold material.

In a fourth aspect, alone or in combination with one or more of the first through third aspects, forming the set of conductive structures includes forming the set of conductive structures on electrical traces of the substrate using a sequence of dry film patterning and electroplating operations, wherein the sequence of dry film patterning and electroplating operations forms the curved profile of heights relative to the surface of the substrate.

In a fifth aspect, alone or in combination with one or more of the first through fourth aspects, forming the set of conductive structures includes forming a layer of a conductive material on the substrate and using a sequence of masking and etching operations, wherein the sequence of masking and etching operations forms the curved profile of heights relative to the surface of the substrate.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

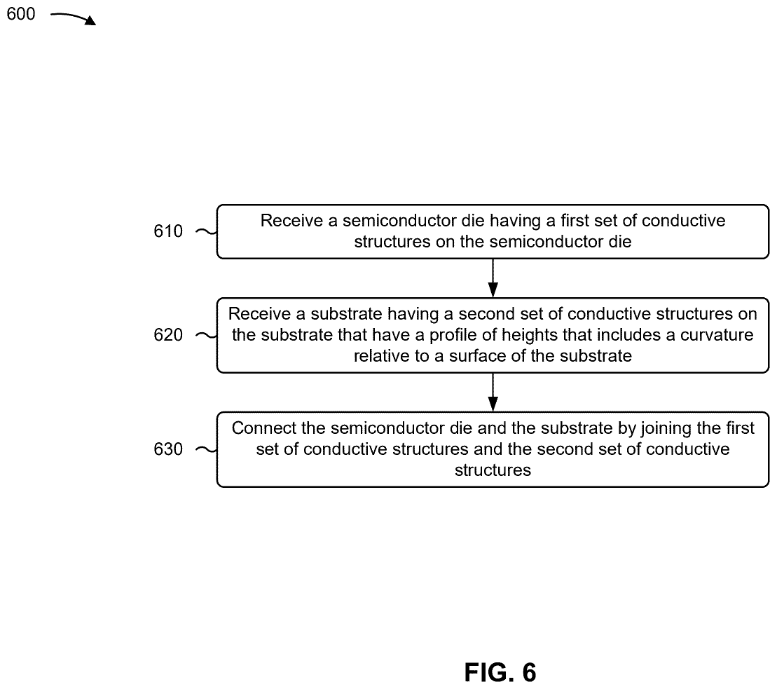

FIG. 6 is a flowchart of an example method 600 associated with forming a semiconductor package described herein (e.g., the apparatus 100). In some implementations, one or more semiconductor processing tools of a semiconductor package assembly facility (e.g., a substrate transport tool, a wafer/die transport tool, a pick-and-place tool, a reflow tool, a dicing tool, a solder screen tool, a solder printing tool, and/or a reflow tool) may perform or may be configured to perform the method 600. Thus, means for performing the method 600 may include the one or more semiconductor processing tools and/or one or more components of the one or more semiconductor processing tools. Additionally, or alternatively, a non-transitory computer-readable medium may store one or more instructions that, when executed by the one or more semiconductor processing tools, cause the one or more semiconductor processing tools to perform the method 600.

As shown in FIG. 6, the method 600 may include receiving a semiconductor die (e.g., the die 115-1) having a first set of conductive structures (e.g., the set of conductive structures 305 or 405) on the semiconductor die (block 610). As further shown in FIG. 6, the method 600 may include receiving a substrate (e.g., the substrate 110 having a second set of conductive structures (e.g., the set of conductive structures 320 or 420) on the substrate and that have a profile of heights that includes a curvature (e.g., the curved profile 360 or 460) relative to a surface (e.g., the surface 365 or 465) of the substrate (block 620). As further shown in FIG. 6, the method 600 may include connecting the semiconductor die and the substrate by joining the first set of conductive structures and the second set of conductive structures (block 630).

The method 600 may include additional aspects, such as any single aspect or any combination of aspects described below and/or described in connection with one or more other methods or operations described elsewhere herein.

In a first aspect, the first set of conductive structures includes an array of solder balls (e.g., the solder balls 315 or 415), and connecting the semiconductor die and the substrate by joining the first set of conductive structures and the second set of conductive structures includes performing a reflow process that joins the solder balls with the second set of conductive structures, causes a first curvature of the semiconductor die (e.g., the curvature 330 or 430), and causes a second, opposite curvature of the substrate (e.g., the curvature 340 or 440).

In a second aspect, alone or in combination with the first aspect, performing the reflow process forms an interface region (e.g., the interface region 325 or 425) including solder joints between the first set of conductive structures and the second set of conductive structures, wherein a radius of curvature of the interface region (e.g., the radius of curvature 350 or 450) is greater than a radius of curvature (e.g., the radius of curvature 335 or 445) of the first curvature.

In a third aspect, alone or in combination with one or more of the first and second aspects, performing the reflow process forms an interface region including solder joints between the first set of conductive structures and the second set of conductive structures, wherein a radius of curvature of the interface region is greater than a radius of curvature of the second, opposite curvature (e.g., the radius of curvature 345 or 445).

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

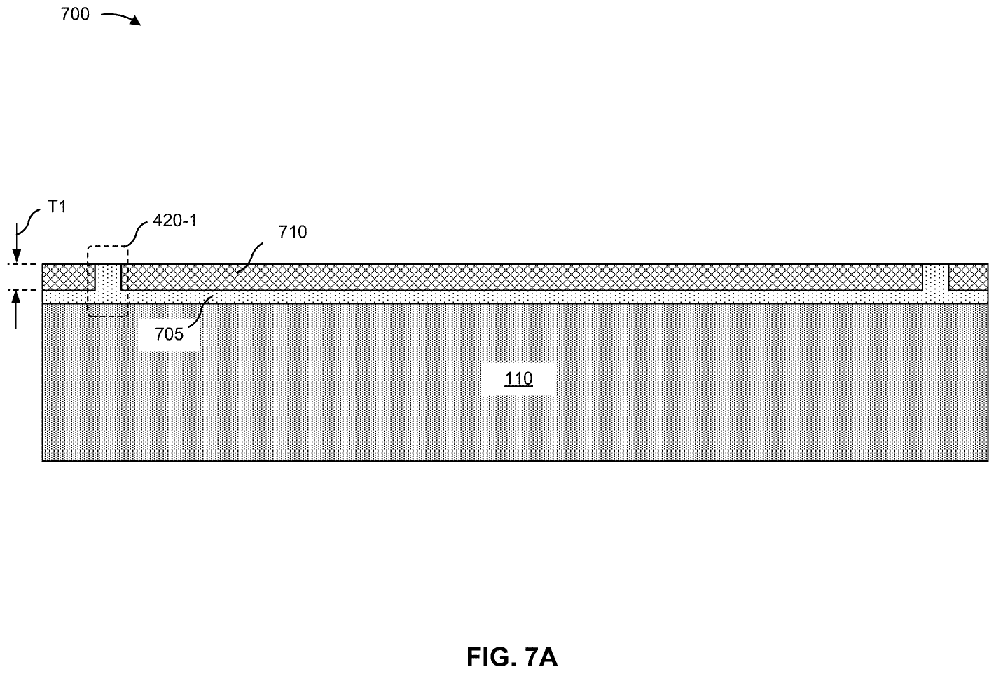

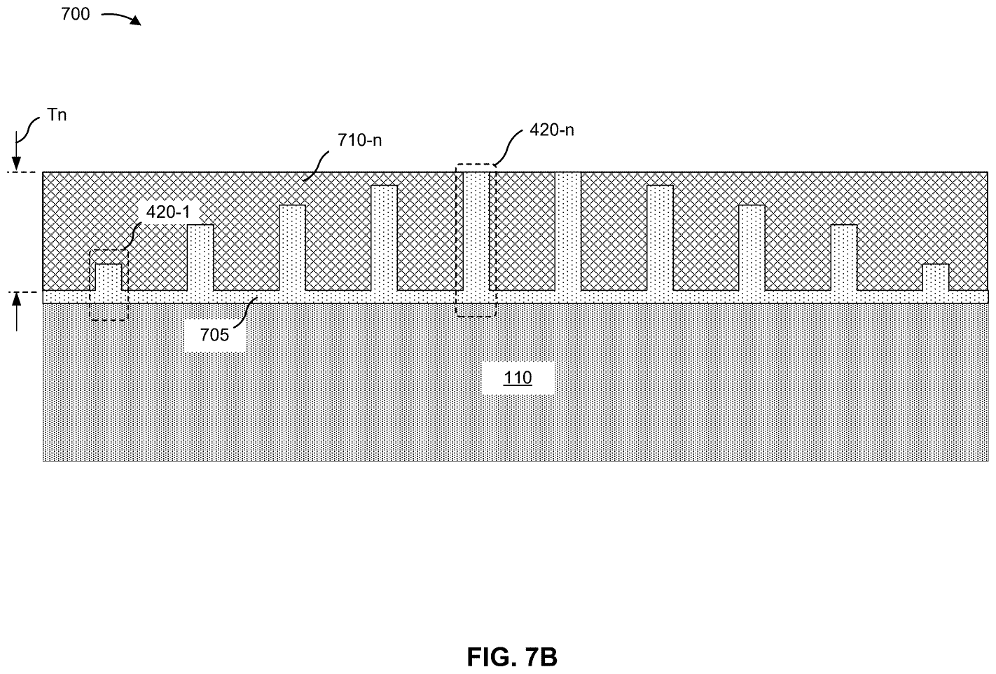

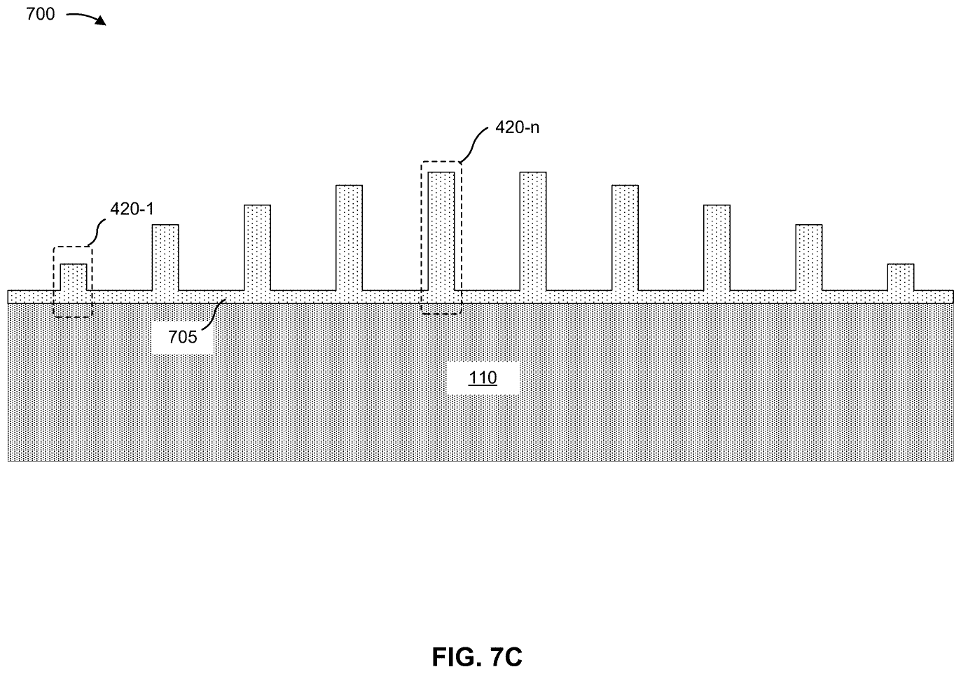

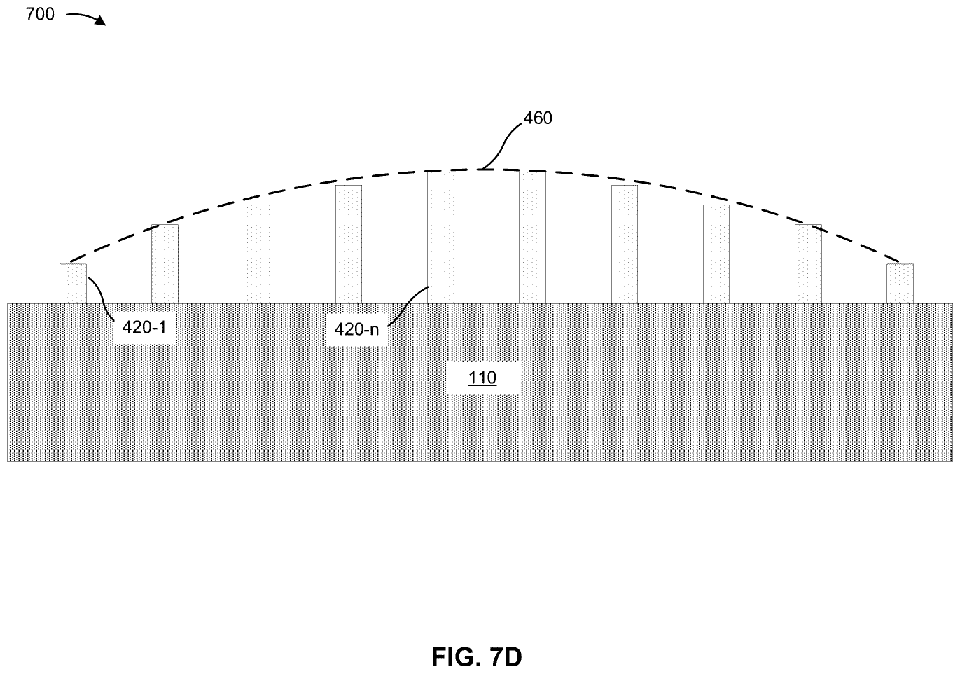

FIGS. 7A-7D show an example series of manufacturing operations 700 that may be performed to form a substrate having a set of conductive structures described herein. In some implementations, the substrate corresponds to the substrate 110 having the set of conductive structures 420 as described in connection with FIGS. 4A and 4B. Furthermore, one or more of the series of manufacturing operations 700 may correspond to one or more of the blocks described in connection with the method 500 of FIG. 5 and/or the method 600 of FIG. 6.

As shown in FIG. 7A, a conductive layer 705 is formed on the substrate 110. The conductive layer 705 may include a conductive material such as a copper material (Cu), an aluminum material (Al), a tin material (Sn), a nickel material (Ni), a silver material (Ag), a gold material (Au), or another suitable conductive material. In some implementations, the conductive layer 705 may be a portion of, or on, an electrical trace or a pad structure of the substrate 110. The conductive layer 705 may be formed using an electroplating technique, a lamination technique, a physical vapor deposition (sputtering) technique, or another suitable deposition technique.

As further shown in FIG. 7A, a masking pattern 710-1 (e.g., a first masking pattern having openings) is formed on and/or over the conductive layer 705. In some implementations, the masking pattern 710-1 includes a dry film material (e.g., a photoresist material) that is laminated onto and/or over the conductive layer 705 and is patterned using lithography patterning and etching techniques. As shown in FIG. 7A, the masking pattern 710-1 (e.g., the dry film material) includes a thickness T1.

As further shown in FIG. 7A, the conductive structures 420-1 are formed on the substrate 110. In some implementations, formation of the conductive structures 420-1 includes using an electroplating technique to build up the conductive structures 420-1 from the conductive layer 705 within openings of the masking pattern 710-1. In some implementations, a height of the conductive structures 420 may be approximately equal to the thickness T1.

As shown in FIG. 7B, the set of conductive structures 420 (e.g., including the conductive structures 420-1 through 420-n) is formed using a sequence (e.g., an iteration) of operations that may use patterning and/or electroplating techniques as described in connection with FIG. 7A. For example, and as shown in FIG. 7B, the masking pattern 710-n includes a thickness Tn and is used to form the conductive structures 420.

FIG. 7C shows the set of conductive structures 420 on the conductive layer 705 after removal of the masking pattern 710-n. In some implementations, removal of the masking patterns 710 includes removing the masking patterns 710 using a chemical stripping technique to expose one or more of the set of conductive structures 420.

FIG. 7D shows the set of conductive structures 420 after removal of portions of the conductive layer 705. As shown in FIG. 7D, the set of conductive structures 420 includes the curved profile 460 as described in connection with FIG. 4B. In some implementations, removal of the portions of the conductive layer 705 includes using a flash etching technique, where another masking pattern that masks the conductive structures 420 is formed over the substrate 110 and unmasked portions of the conductive layer 705 are removed by rapidly heating and/or vaporizing the unmasked portions.

Other series of operations may be used to form the set of conductive structures 420 having the curved profile 460. As an example, another series of operations may include forming a single layer of a conductive material on the substrate 110 and using a sequence of masking and etching operations. The series of masking and etching operations may sequentially remove portions of the single layer of conductive material to different depths to form the curved profile 460. As another example, another series of operations may include a sequence of deposition and/or printing (e.g., individual printing or bulk screen printing) operations to form the set of conductive structures 420 having the curved profile 460.

As indicated above, FIGS. 7A-7D are provided as an example. Other examples may differ from what is describe with regard to FIGS. 7A-7D.

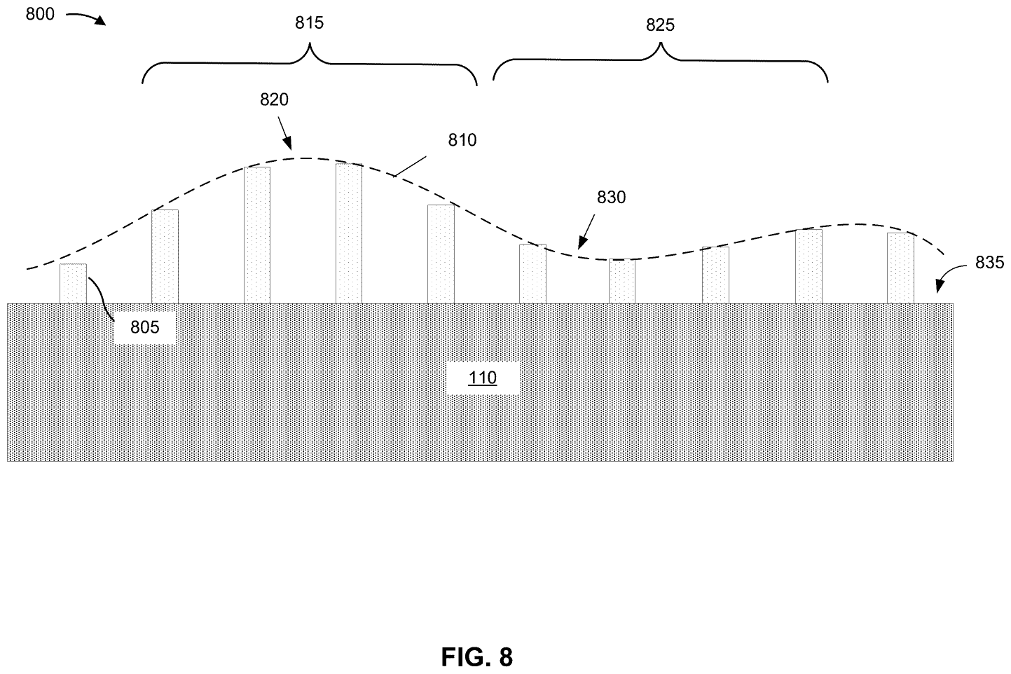

FIG. 8 is a diagram of an example implementation 800 described herein. The implementation 800 may correspond to the region 145 of the apparatus 100 of FIG. 1. Alternatively, the implementation 800 may correspond to a semiconductor package including a single die (e.g., the die 115-1). The implementation 800 includes a set of conductive structures 805 having a profile 810. As shown in FIG. 8, the profile 810 is an asymmetric profile (e.g., includes an asymmetric curvature) which may be based on an expected warpage of a die (e.g., the die 115-1) and/or the substrate 110.

As shown in FIG. 8, the profile 810 includes a portion 815 having a curvature 820 and a portion 825 having a curvature 830. As shown in FIG. 8, the curvatures 820 and 830 may be opposite curvatures.

In some implementations, and as shown in FIG. 8, at least a portion of the profile 810 includes a convex curvature (e.g., the portion 815 including the curvature 820 that curves away from a surface 835 of the substrate 110). Furthermore, and in some implementations and as shown in FIG. 8, at least a portion of the profile 810 includes a concave curvature (e.g., the portion 825 that includes the curvature 830 that curves toward the surface 835 of the substrate 110).

As indicated above, FIG. 8 is provided as an example. Other examples may differ from what is described with respect to FIG. 8.

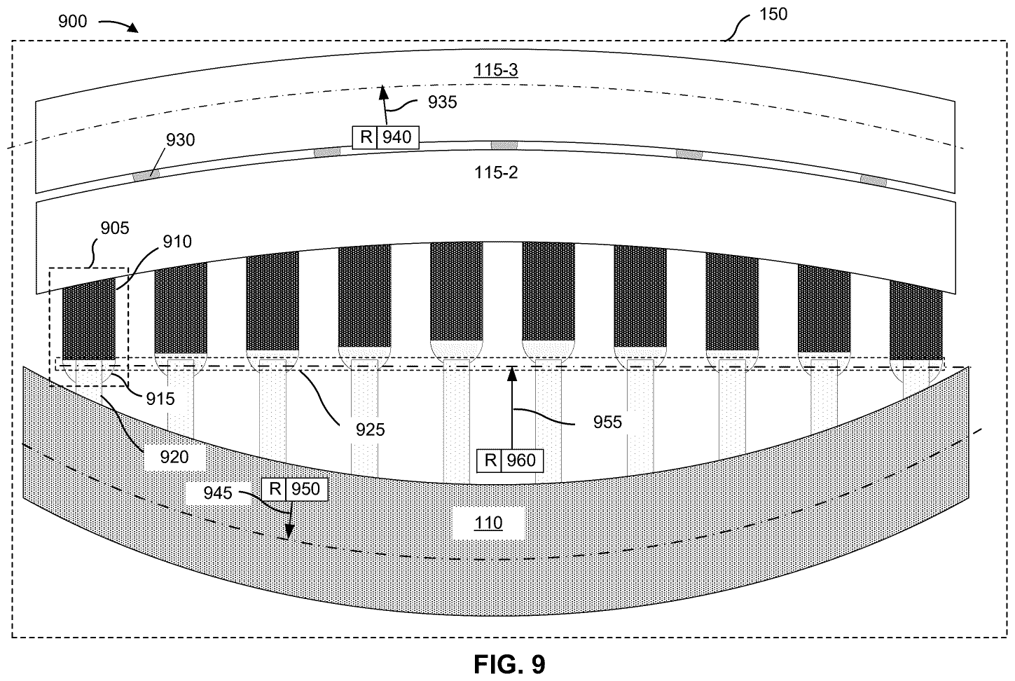

FIG. 9 is a diagram of an example implementation 900 described herein. The implementation 900 may correspond to the region 150 of the apparatus 100 of FIG. 1. Alternatively, the implementation 900 may correspond to a semiconductor package including a stack of multiple dies (e.g., the dies 115-2 and 115-3).

In implementation 900, a reflow process that joins the substrate 110 and the stack of multiple dies induces a first warpage to the substrate 110 and a second warpage to the stack of multiple dies. In implementation 900, the first warpage extends toward the stack of multiple dies, and the second warpage extends toward the substrate 110. In other words, the warpages of the substrate 110 and the stack of multiple dies are opposite curvatures that extend toward one another. However, and in some implementations, the warpages of the substrate 110 and the stack of multiple dies are opposite curvatures that extend away from one another.

As shown in FIG. 9, a set of conductive structures 905 is on the die 115-2. The set of conductive structures 905 may include pillar structures 910 and solder balls 915 that are on (e.g., connected with) the pillar structures 910. The pillar structures 910 may include a conductive material such as a copper material (Cu), a gold material (Au), a silver material (Ag), or another suitable conductive material. The solder balls 915 may include a solderable alloy such as a tin-lead (Sn—Pb) alloy, a tin-silver-copper (Sn—Ag—Cu) alloy, a tin-copper (Sn—Cu) alloy, or another suitable solderable alloy.

As further shown in FIG. 9, a set of conductive structures 920 is on the substrate 110. The set of conductive structures 920 may correspond to pad structures, electrical traces, and/or bumps that are on the substrate 110, among other examples. The set of conductive structures 920 may include a combination of one or more conductive materials such as a copper material (Cu), an aluminum material (Al), a tin material (Sn), a nickel material (Ni), a silver material (Ag), a gold material (Au), or another suitable conductive material.

The sets of conductive structures 905 and 920 join within an interface region 925. The interface region 925 includes solder joints between the solder balls 915 and the set of conductive structures 920, where the solder joints are formed by an SMT and reflow process that temporarily elevates a temperature of the solder balls 915 to a liquid or semi-liquid phase, joins the solder balls 915 with conductive structures 920, and cools the temperature of the solder balls 915 to a solid phase that forms the solder joints.

As shown in FIG. 9, the dies 115-2 and 115-3 join together using solder balls 930. The solder balls 930 may include a solderable alloy such as a tin-lead (Sn—Pb) alloy, a tin-silver-copper (Sn—Ag—Cu) alloy, a tin-copper (Sn—Cu) alloy, or another suitable solderable alloy and may connect pad structures of the die 115-2 with backside redistribution layers and/or traces of the die 115-3. Alternatively, the dies 115-2 and 115-3 may be joined with an adhesive (e.g., a layer of tape) or another suitable bonding structure.

In some implementations, the dies 115-2 and 115-3 are memory dies used as part of a high bandwidth memory (HBM) application. In other words, an apparatus including the dies 115-2 and 115-3 (e.g., the apparatus 100 of FIG. 1) may be a semiconductor package used for an HBM application such as an artificial intelligence application (AI), a machine learning application, a high-performance computing application (HPC), or a virtual reality application, among other examples.

As shown in FIG. 9, the stack of multiple dies includes a curvature 935 having a radius of curvature 940 and the substrate 110 includes a curvature 945 having a radius of curvature 950. Further, and as shown in FIG. 9, the interface region 925 includes a curvature 955 having a radius of curvature 960, where the curvature 960 is greater than the radius of curvature 940 and/or the radius of curvature 950. In other words, the interface region 925 is “flatter” than the substrate 110 and/or the stack of multiple dies including the dies 115-2 and 115-3.

As indicated above, FIG. 9 is provided as an example. Other examples may differ from what is described with respect to FIG. 9.

In some implementations, a semiconductor device assembly includes a semiconductor die, comprising: a first set of conductive structures on the semiconductor die; and a substrate joined with the semiconductor die and comprising: a second set of conductive structures on the substrate, wherein a profile of heights of the second set of conductive structures relative to a surface of the substrate includes a curvature, and wherein the second set of conductive structures connect with the first set of a set of conductive structures.

In some implementations, a semiconductor device assembly includes a semiconductor die comprising a first set of conductive structures on the semiconductor die; and a substrate coupled with the semiconductor die and comprising a second set of conductive structures on the substrate, wherein a profile of heights of the second set of conductive structures relative to a surface of the substrate includes a curvature, and wherein the second set of conductive structures couples with the first set of conductive structures.

In some implementations, a method includes forming a substrate; and forming, on the substrate, a set of conductive structures having a curved profile of heights relative to a surface of the substrate.

In some implementations, a method includes receiving a semiconductor die having a first set of conductive structures on the semiconductor die; receiving a substrate having a second set of conductive structures on the substrate and having a profile of heights that includes a curvature relative to a surface of the substrate; and connecting the semiconductor die and the substrate by joining the first set of conductive structures and the second set of conductive structures.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a semiconductor die, comprising:
a first set of conductive structures on the semiconductor die; and
a substrate joined with the semiconductor die and comprising:
a second set of conductive structures on the substrate,
wherein a profile of heights of the second set of conductive structures relative to a surface of the substrate includes a curvature, and
wherein the second set of conductive structures connect with the first set of a set of conductive structures.

2. The semiconductor device assembly of claim 1, wherein the profile is a two-dimensional profile and the curvature is a convex curvature that curves away from the surface.

3. The semiconductor device assembly of claim 1, wherein the profile is a three-dimensional profile and the curvature is a convex curvature that curves away from the surface.

4. The semiconductor device assembly of claim 1, wherein the profile is a two-dimensional profile and the curvature is a concave curvature that curves toward the surface.

5. The semiconductor device assembly of claim 1, wherein profile is a three-dimensional profile and the curvature is a concave curvature that curves toward the surface.

6. The semiconductor device assembly of claim 1, wherein the curvature is a symmetric curvature.

7. The semiconductor device assembly of claim 1, wherein the curvature is an asymmetric curvature.

8. The semiconductor device assembly of claim 1, wherein the curvature is a first curvature, wherein the profile includes a first portion that includes the first curvature, and wherein the profile further comprises:
a second portion having a second curvature that is opposite the first curvature.

9. A semiconductor device assembly, comprising:
a semiconductor die comprising a first set of conductive structures on the semiconductor die; and
a substrate coupled with the semiconductor die and comprising a second set of conductive structures on the substrate,
wherein a profile of heights of the second set of conductive structures relative to a surface of the substrate includes a curvature, and
wherein the second set of conductive structures couples with the first set of conductive structures.

10. The semiconductor device assembly of claim 9, wherein the second set of conductive structures comprises:
an array of pad structures.

11. The semiconductor device assembly of claim 9, wherein the second set of conductive structures comprises:
an array of electrical traces.

12. The semiconductor device assembly of claim 9, wherein the first set of conductive structures comprises:
an array of solder balls on an array of pillar structures,
wherein the array of solder balls forms solder joints with the second set of conductive structures along an interface region that joins the solder balls with the second set of conductive structures.

13. The semiconductor device assembly of claim 9, wherein the substrate corresponds to:
a printed circuit board substrate,
a ceramic substrate, or
a silicon substrate.

14. The semiconductor device assembly of claim 9, wherein the semiconductor die corresponds to:
a memory integrated circuit die,
a logic integrated circuit die, or
an application-specific integrated circuit die.

15. The semiconductor device assembly of claim 9, wherein the semiconductor die is a first semiconductor die, and further comprising:
a second semiconductor die stacked on the first semiconductor die.

16. A method, comprising:
forming a substrate; and
forming, on the substrate, a set of conductive structures having a curved profile of heights relative to a surface of the substrate.

17. The method of claim 16, wherein forming the set of conductive structures having the curved profile of heights relative to the surface of the substrate includes:
forming at least a portion of the set of conductive structures to include a convex profile of heights that faces away from the surface of the substrate.

18. The method of claim 16, wherein forming the set of conductive structures having the curved profile of heights relative to the surface of the substrate includes:
forming at least a portion of the set of conductive structures to include a concave profile of heights that faces toward the surface of the substrate.

19. The method of claim 16, wherein forming the set of conductive structures includes forming the set of conductive structures from one or more of:
a copper material,
an aluminum material,
a tin material,
a nickel material,
a silver material, or
a gold material.

20. The method of claim 16, wherein forming the set of conductive structures includes:
forming the set of conductive structures on electrical traces of the substrate using a sequence of dry film patterning and electroplating operations,
wherein the sequence of dry film patterning and electroplating operations forms the curved profile of heights relative to the surface of the substrate.

21. The method of claim 16, wherein forming the set of conductive structures includes:
forming a single layer of a conductive material on the substrate and using a sequence of masking and etching operations,
wherein the sequence of masking and etching operations forms the curved profile of heights relative to the surface of the substrate.

22. A method, comprising:
receiving a semiconductor die having a first set of conductive structures on the semiconductor die;
receiving a substrate having a second set of conductive structures on the substrate that have a profile of heights that includes a curvature relative to a surface of the substrate; and
connecting the semiconductor die and the substrate by joining the first set of conductive structures and the second set of conductive structures.

23. The method of claim 22, wherein the first set of conductive structures includes an array of solder balls, and
wherein connecting the semiconductor die and the substrate by joining the first set of conductive structures and the second set of conductive structures includes:
performing a reflow process that joins the solder balls with the second set of conductive structures, causes a first curvature of the semiconductor die, and causes a second, opposite curvature of the substrate.

24. The method of claim 23, wherein performing the reflow process forms an interface region including solder joints between the first set of conductive structures and the second set of conductive structures,
wherein a radius of curvature of the interface region is greater than a radius of curvature of the first curvature.

25. The method of claim 23, wherein performing the reflow process forms an interface region including solder joints between the first set of conductive structures and the second set of conductive structures,
wherein a radius of curvature of the interface region is greater than a radius of curvature of the second, opposite curvature.
